(19) United States
(12) Patent Application Publication
(10) Pub. No.: US 2026/0156849 A1
(43) Pub. Date: Jun. 4, 2026

(54) BIPOLAR JUNCTION TRANSISTOR WITH DIRECT BACKSIDE CONTACT

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US)

(21) Appl. No.: 18/967,584

(22) Filed: Dec. 3, 2024

(51) Int. Cl. H10D 10/80; H01L 21/762; H10D 10/01; H10D 62/10

(52) U.S. Cl. CPC H10D 10/821; H10D 10/021; H10D 10/051; H10D 62/102; H10W 10/014; H10W 10/17

(57) ABSTRACT

A semiconductor device includes a base including a base contact, an emitter including an emitter contact, a well region below the base and the emitter, an extrinsic base between the base and the well region, and a collector located below the well region and on a backside of the semiconductor device. The base contact and the emitter contact are connected to a frontside of the semiconductor device.

### BACKGROUND

### Technical Field

The present disclosure generally relates to semiconductors, and more particularly, to bipolar junction transistors with backside contact structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. Various functionalities, including processing and storage, are increasingly being integrated within a single chip, enabling more compact and efficient systems.

### SUMMARY

According to an embodiment, a semiconductor device includes a base having a base contact, an emitter having an emitter contact, a well region below the base and the emitter, an extrinsic base between the base and the well region, and a collector located below the well region and on a backside of the semiconductor device. The base contact and the emitter contact are connected to a frontside of the semiconductor device

In one embodiment, the semiconductor device includes a bottom dielectric layer (BILD) below the first well region, and a backside interconnect between the collector device to the BILD.

In one embodiment, each of the base and the emitter includes a set of P-type doped regions and a set of N-type doped regions, and a gate region.

In one embodiment, the base contact and the emitter contact are connected to the frontside of the semiconductor device via a frontside interconnect.

In one embodiment, the semiconductor device is electrically connected to a back end of line (BEOL) through a via and the base contact and the emitter contact.

In one embodiment, the semiconductor device includes shallow trench isolation (STI) on opposite ends of the semiconductor device, and interlayer dielectric (ILD) located over the base and the emitter.

In one embodiment, the semiconductor device includes a backside metal over the backside interconnect, a backside contact over the backside metal, wherein the collector is located over the backside contact, and wherein the collector is encapsulated by the well region.

In one embodiment, each of the base and the emitter includes alternative layers extended horizontally between two adjacent gate regions.

In one embodiment, the alternative layers include silicon.

According to an embodiment, a method of fabricating a semiconductor device includes forming a base including a base contact, wherein the base is doped with a first dopant to a first level of doping, forming an emitter including an emitter contact, forming a well region below the base and the emitter, forming a collector located below the well region and on a backside of the semiconductor device, forming an extrinsic base between the base and the well region, and establishing an electrical connection between the base contact and the emitter contact and a frontside of the semiconductor device.

In one embodiment, the method includes forming a bottom dielectric layer (BILD) below the first well region, and forming a backside interconnect between the collector device to the BILD.

In one embodiment, forming each of the base and the emitter includes forming a set of P-type doped regions and a set of N-type doped regions, and forming a gate region.

In one embodiment, the method includes establishing the electrical connection between the base contact and the emitter contact and a frontside of the semiconductor device via a frontside interconnect.

In one embodiment, the method includes establishing an electrical connection between the semiconductor device and a back end of line (BEOL) through a via and the base contact and the emitter contact.

In one embodiment, the method includes forming shallow trench isolation (STI) on opposite ends of the semiconductor device, and forming interlayer dielectric (ILD) located over the base and the emitter.

In one embodiment, the method includes forming a backside metal over the backside interconnect, forming a backside contact over the backside metal, forming the collector over the backside contact, and encapsulating the collector by the well region.

In one embodiment, forming each of the base and the emitter includes forming alternative layers extended horizontally between two adjacent gate regions.

In one embodiment, the alternative layers include silicon.

In one embodiment, the method includes forming the base with SiGe.

According to an embodiment, a semiconductor device includes a base having a base contact, the base located on a frontside of the semiconductor device, an emitter having an emitter contact, the emitter located on the frontside of the semiconductor device, a well region below the base and the emitter, and a collector located on a backside of the semiconductor device.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a heterogenous bipolar transistor, in accordance with some embodiments.

FIG. 2 illustrates a bipolar junction transistor, in accordance with some embodiments.

FIG. 3 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

Backside interconnect technology has emerged as the industry's preferred direction for advancing semiconductor device performance and scaling. By relocating interconnects to the backside of the wafer, designers can alleviate front-side wiring congestion, reduce parasitic capacitance and resistance, and improve overall device efficiency. This shift addresses the challenges posed by continued device miniaturization and the increasing demand for higher performance in integrated circuits.

Direct backside connection technology involves creating electrical connections on the backside of the semiconductor wafer, providing a more efficient pathway for power delivery and signal routing. When combined with low-temperature epitaxial growth processes at the backside, this approach enables the fabrication of a full suite of vertical bipolar transistors. Low-temperature epi growth is crucial because it preserves the integrity of the front-side devices by preventing thermal degradation or dopant diffusion that could occur at higher temperatures.

Vertical bipolar transistors are advantageous in high-frequency and high-power applications due to their superior current-carrying capabilities and faster switching speeds compared to their lateral counterparts. By exploiting backside interconnects and low-temperature epi growth, these vertical devices can be integrated directly into the existing semiconductor architecture without significantly increasing the complexity of the fabrication process.

The integration of vertical bipolar transistors via backside technology offers several benefits. It enhances device density by utilizing the backside of the wafer, effectively doubling the available real estate for circuitry. This approach also improves thermal management, as the backside connections provide an additional pathway for heat dissipation, which is essential for maintaining device reliability at high operating speeds.

Moreover, the combination of backside interconnects and vertical bipolar transistors aligns with the industry's move towards three-dimensional (3D) integration and heterogeneous integration. By stacking devices vertically and connecting them through backside vias and interconnects, manufacturers can achieve greater functionality and performance within a smaller footprint. The methodology supports the development of advanced semiconductor technologies, such as those required for artificial intelligence, high-speed communication, and other data-intensive applications.

The present disclosure addresses these challenges by introducing a bipolar junction transistor, BJT, that incorporates direct backside contact technology to enhance performance and integration within semiconductor devices. In this configuration, the BJT is designed with electrical contacts formed on the backside of the semiconductor wafer, rather than the traditional front-side approach. Such a method allows for more efficient current flow, improved thermal management, and increased device density. In a typical BJT, which includes an emitter, base, and collector, the collector region is often the target for backside contact. By establishing a direct electrical connection to the collector on the backside of the wafer, the device reduces parasitic resistances and capacitances associated with front-side interconnects. Such a configuration provides a shorter and more direct path for charge carriers, enhancing the transistor's switching speed and overall electrical performance.

The use of backside contacts alleviates congestion on the front side of the wafer, freeing up valuable surface area for additional circuitry and active components. This is particularly beneficial in advanced semiconductor technologies where scaling down device dimensions is critical. By moving some of the interconnections to the backside, the design can achieve higher integration densities without increasing the chip's footprint, allowing for more complex and powerful integrated circuits.

Thermal management is another advantage of incorporating direct backside contacts in a BJT. During operation, BJTs can generate substantial amounts of heat, especially in high-frequency or high-power applications. The backside contact provides an efficient thermal pathway for dissipating heat away from the active regions of the transistor. Such an improved heat dissipation helps maintain improved (e.g., optimal) operating temperatures, enhancing the reliability and longevity of the device.

Fabricating a BJT with direct backside contact technology involves advanced manufacturing processes that ensure compatibility with existing front-side structures. Low-temperature epitaxial growth techniques are often employed to deposit semiconductor layers on the backside without damaging the front-side components. These processes preserve the integrity of the device's active regions while enabling the formation of high-quality electrical contacts on the backside. The integration of a BJT using Direct Backside Contact Technology offers multiple benefits:
Enhanced electrical performance: Reduced parasitic effects lead to faster switching speeds and better overall transistor performance.
Increased integration density: Freeing up front-side space allows for more components to be integrated into the same chip area.
Improved thermal management: Efficient heat dissipation through the backside enhances device reliability, especially under demanding operating conditions.
Scalability: The technology is compatible with advanced semiconductor nodes, supporting continued device miniaturization.

Accordingly, the teachings herein provide methods and systems of semiconductor device formation with the direct backside contact. The techniques described herein may be implemented in a number of ways. Example implementations are provided below with reference to the following figures.

Example Semiconductor Device with Direct Backside Contact Structure

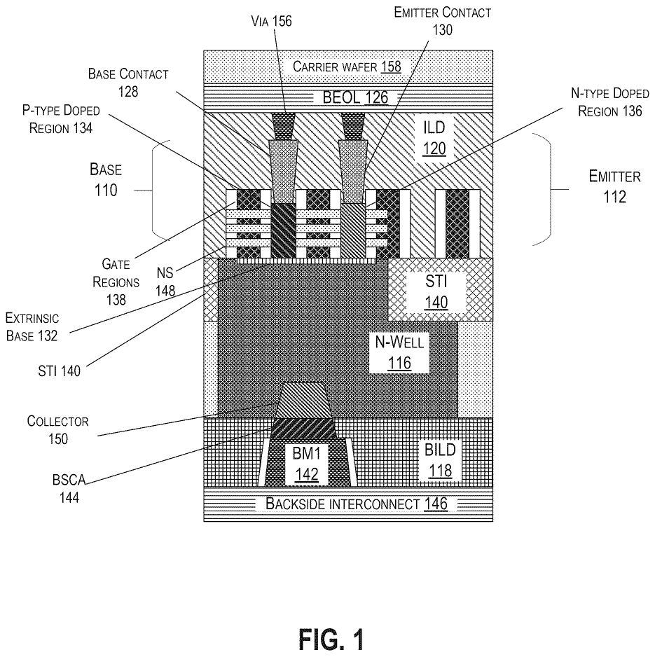

Reference now is made to FIG. 1, which is a simplified cross-section view of a semiconductor device, consistent with an illustrative embodiment. The semiconductor device includes an arrangement of various regions and interconnects that facilitate controlled current flow through designated pathways within the structure. This arrangement supports improved device efficiency and stability, especially in applications requiring high-speed switching and efficient power amplification, such as in radio frequency (RF) applications or integrated circuit designs.

This semiconductor device features several interconnected regions, each with a specific function. In some embodiments, the semiconductor device includes a base 110, an emitter 112, a collector 114, a well region 116, and a bottom interlayer dielectric, BILD 118. Additionally, interlayer dielectric, ILD 120, provides electrical isolation, while a frontside interconnect and a backside interconnect 146 ensure connectivity with other circuitry components, particularly the back end of line, BEOL 126. In some embodiments, the frontside interconnect can be within the BEOL 126. The combination of these components achieves an improved (e.g., optimal) balance of conductivity and isolation, supporting reliable performance across various operational conditions.

The base 110 and emitter 112 are positioned on the frontside of the semiconductor device and serve as regions for current control and amplification. The base contact 128 and emitter contact 130 provide connectivity to external circuits, with connections routed through the frontside interconnect that interface with the BEOL 126. Such a frontside configuration enables efficient connectivity without compromising the integrity of the structure or interfering with other device regions. Each of the base contact 128 and emitter contact 130 can establish connections between the semiconductor device and the BEOL 126 through a via 156 and the second via. The base contact 128 and emitter contact 130 can ensure efficient electrical routing and connectivity within the semiconductor device. The fabrication of the base contact 128 and emitter contact 130 can involve lithography and etching processes to define the contact area. The base contact 128 and emitter contact 130 can be made using conductive materials such as copper (Cu) or tungsten (W)

The well region 116, positioned below both the base 110 and emitter 112, controls electron movement within the semiconductor device. Located between the base 110 and the well region 116 is an extrinsic base 132, which enhances semiconductor device performance by reducing parasitic capacitances and allowing for faster switching speeds. The well region 116 also encapsulates the collector 150, which can be a doped region, further stabilizing the semiconductor device and preventing unintended current paths. Encapsulation by the well region 116 provides an additional layer of isolation for the collector 150, helping to protect against interference from other components.

Below the well region 116 is the collector 114, e.g., ground, which is positioned on the backside of the semiconductor device. Such a backside configuration allows the collector 114 to capture electrons emitted from the emitter 112 and facilitates efficient current flow across the semiconductor device. The collector's placement on the backside enhances management of high-frequency currents and power dissipation, making the semiconductor device suitable for high-performance applications where minimal energy loss is a relevant consideration.

The base 110 and emitter 112 incorporate both the P-type doped regions 134 and the N-type doped regions 136, facilitating distinct regions for electron and hole mobility. A P-type doped region, which is a semiconductor area doped with elements such as boron to create positively charged “holes,” enhances the mobility of electrons. The N-type doped region, in contrast, is doped with elements such as phosphorus to add extra electrons, thereby increasing conductivity. The doped regions establish well-defined boundaries for electron and hole conduction, enhancing the overall efficiency of the semiconductor device. The controlled doping configurations also prevent unwanted recombination of electrons and holes, thus maintaining the integrity of the current flow and supporting stable device operation.

The gate regions 138 in the base 110 and emitter 112 provide control over current flow, allowing the semiconductor device to achieve rapid switching without sacrificing stability. Positioned adjacent to the P-type doped regions 134 and the N-type doped regions 136, the gate regions 138 help to modulate the flow of electrons between the base 110 and the emitter 112, which allows the semiconductor device to perform reliably under varying operational conditions, including high-frequency or high-power applications. Gate regions are structures within the semiconductor device that regulate electron flow between adjacent regions, such as the base 110 and the emitter 112, thus providing control over current switching and stability.

Shallow trench isolation, STI 140, is implemented along the edges of the semiconductor device to isolate functional areas of the device, such as the base 110, the emitter 112, and the collector 114, from surrounding components. The STI 140 confines electron movement to intended regions only, enhancing semiconductor device stability and reducing interference between adjacent areas. There is a carrier wafer 158 above the BEOL 126.

In addition to STI 140, the ILD 120 is positioned over the active regions of the base 110 and the emitter 112 to further insulate these components. By preventing unintended current paths, the ILD 120 ensures that the semiconductor device's internal currents flow along predetermined routes, optimizing control and reducing power losses. The ILD 120 can serve as an insulating layer that separates various conducting layers and components within the semiconductor device. The ILD 120 can be a layer of insulating material to electrically isolate and provide mechanical support between different layers of conducting and active components. The ILD 120 can enable efficient signal transmission, reduce crosstalk, and ensure the proper functioning of the semiconductor device. In an embodiment, the ILD 120 can electrically isolate adjacent conducting layers or active components in the semiconductor device. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the passive device's structure.

On the backside of the semiconductor device, the device integrates elements that facilitate connectivity to external circuits while preserving the functionality of the semiconductor device. A backside metal (e.g., interconnect), BM1 142, and a backside contact, BSCA 144, provide points of connectivity for backside components. These components, in turn, link the collector 114 to external circuitry, enabling the semiconductor device to handle high frequencies and power levels. The BM1 142 serves as a conductive layer that enhances the efficiency of signal transfer, allowing for seamless connectivity and further supporting high-speed performance.

The BILD 118 is located below the well region 116, insulating the backside components from other regions of the semiconductor device. The BILD 118 maintains electrical isolation, preventing unintended current flow between the backside and frontside regions. Additionally, a backside interconnect 146 bridges the collector 114 and the BILD 118, establishing a stable connection that supports the semiconductor device's performance requirements without compromising its isolation. Such an arrangement of the BILD 118 and the backside interconnect 146 allows for efficient signal routing through the semiconductor device, ensuring that connectivity is both reliable and insulated from other pathways.

In several embodiments, the BILD 118 can provide structural support to the semiconductor device by maintaining the mechanical integrity and stability of the semiconductor device. The BILD 118 can further help prevent the warping, bending, or cracking of the substrate, particularly during the manufacturing process or subsequent handling. The BILD 118 can ensure that the semiconductor device remains mechanically robust and maintains its dimensional stability.

In an embodiment, the BILD 118 can also serve as a planarization layer in the semiconductor device fabrication process. As various layers are deposited and patterned on the front side of the semiconductor device, irregularities or topographic variations may arise. The BILD 118 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 118 can contribute to improved overall passive device performance. In several embodiments, BILD 118 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

The semiconductor device further includes alternative horizontal layers, e.g., nanosheet gates (NS 148), extended within the base 110 and the emitter 112, positioned between adjacent gate regions. The NS 148 enhance performance by increasing electron and hole mobility within the base 110 and the emitter 112. Silicon can be used in the NS 148 for its electrical properties, which include high carrier mobility and low power consumption. The NS 148 improve the stability of the semiconductor device's structure and contribute to a reliable current flow across the base 110 and the emitter 112, enhancing the semiconductor device's response in high-speed and high-power applications.

In addition to the NS 148, the semiconductor device utilizes a collector positioned over the BSCA 144 and encapsulated by the well region 116. The collector 150 prevents electron leakage and maintains controlled current flow through the semiconductor device. The well region's encapsulation of the collector 150 creates a barrier that prevents interference from external sources, preserving the integrity of the current paths and ensuring stable device performance.

The semiconductor device can be configured as a vertical heterojunction bipolar transistor (HBT), for high-speed and high-frequency applications. In this configuration, the semiconductor device is built with distinct material layers and doping types that optimize electron mobility and control within the device. The base 110 can be formed using a lightly doped P-type silicon-germanium (SiGe) layer. Silicon-germanium can be selected for its electron mobility and high-frequency performance compared to pure silicon, allowing the base 110 to support efficient electron flow while maintaining excellent current control. The P-type doping of the base 110 introduces “holes” as majority carriers, which, in combination with the intrinsic properties of silicon-germanium, improves the current gain and switching speed of the device. The low doping concentration in the base 110 can reduce (e.g., minimize) parasitic resistance, which helps reduce base 110 recombination losses and improves the HBT's overall current gain.

The collector 114, positioned vertically beneath the base 110 in the HBT structure, can be formed through a deposition process involving low-temperature epitaxial growth of a highly doped N-type layer. Epitaxial growth which is a process in which silicon or silicon-germanium layers are grown in a controlled environment, enables control over doping concentrations and structural quality. The N-type doping in the collector 114 introduces additional electrons as majority carriers, ensuring efficient collection of charge carriers emitted from the base 110. The high doping level (n+) in the collector 114 reduces (e.g., minimizes) resistance in this layer, reducing power loss and enabling the semiconductor device to handle higher current densities effectively. Low-temperature deposition is used to maintain the structural integrity of the semiconductor device while preventing dopant diffusion, which preserves the abrupt junctions between the base 110 and the collector 114 necessary for improved (e.g., optimal) HBT operation.

The entire semiconductor device is constructed within an N-well tub, e.g., the well region 116, which provides a foundational region that supports and isolates the HBT structure. The N-well tub, which can be lightly doped, establishes an electrically neutral environment that helps to stabilize the device by reducing unwanted current leakage and reducing (e.g., minimizing) parasitic capacitance. The well region 116 can provide additional isolation for the HBT, preventing interaction with surrounding circuitry or substrate regions and ensuring that the device can operate independently without interference.

Vertical isolation within the semiconductor device can be achieved using a low-k ILD, which surrounds the semiconductor regions and isolates the active components of the HBT. Low-k materials are chosen for their reduced dielectric constant, which helps to reduce (e.g., minimize) parasitic capacitance between adjacent layers in the vertical stack. The reduction in capacitance allows for faster switching speeds and lowers power consumption, making low-k dielectrics ideal for high-frequency applications. The low-k ILD also provides mechanical stability to the structure, supporting the semiconductor device's vertical layers and preventing structural deformation over time.

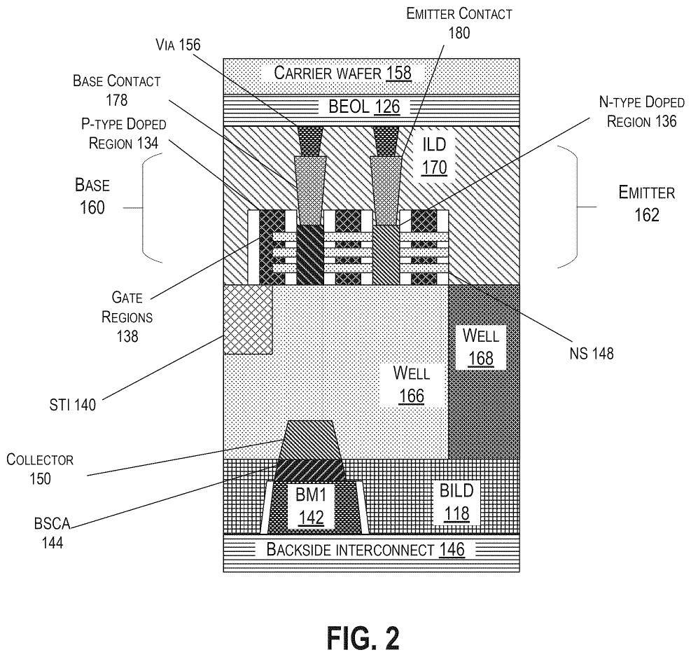

Reference now is made to FIG. 2, which is a simplified cross-section view of a semiconductor device, consistent with an illustrative embodiment. In some embodiments, the semiconductor device is configured as a vertical bipolar junction transistor (BJT), designed to optimize vertical current flow and facilitate high-frequency performance. In such embodiments, the semiconductor device includes a base 160, an emitter 162, a well region 166, and a collector 150.

The base 160, located on the frontside of the semiconductor device, includes a base contact 178 that allows connection to external circuitry. In some embodiment, the base 160 is integrated directly within the well region 166 rather than an extrinsic base layer. This simplifies the semiconductor device structure and enhances conductivity by reducing the number of layers in the current path. The P-type doping introduces holes as the primary carriers in the base 160, which interact with electrons from the N-type collector. This configuration helps control electron flow through the semiconductor device, improving performance at high frequencies.

Adjacent to the base 160 is the emitter 162, which resides on the frontside of the semiconductor device and includes an emitter contact 180. Similar to the base contact 178, the emitter contact 180 connects to the frontside interconnect, facilitating straightforward connections to the device's external circuitry. The positioning of both the base 160 and emitter 162 on the frontside allows for efficient wiring and reduces signal loss that might otherwise occur with backside connections.

The well region 166, which can be a P-well or an N-well, is positioned below the base 160 and the emitter 162. The use of a P-well as the well region 166 introduces additional isolation, creating a more defined separation between the base and the surrounding regions. The well region 166 helps control charge carrier movement, further enhancing the semiconductor device's performance and providing stability against potential leakage currents. In some embodiments, a well region 168 is adjacent to the well region 166.

Below the well region 166 and vertically underneath the base 160 lies the collector 164. The collector 164 captures the electrons flowing from the emitter 162, through the base 160, and down toward the backside of the semiconductor device. Such a vertical arrangement allows for efficient current flow through the semiconductor device, reducing the parasitic resistance commonly associated with lateral configurations and improving high-speed switching.

The collector 164 is formed by depositing a low-temperature N+ epitaxial layer. The N+ doping introduces a high concentration of electrons as majority carriers in the collector 164, optimizing it for collecting the charge carriers that pass through the base 160. The use of a low-temperature epitaxial deposition ensures reduced (e.g., minimal) diffusion of dopants between regions, maintaining well-defined boundaries that enhance the performance and stability of the transistor.

The collector 164 is positioned on the backside of the semiconductor device, in contrast to the frontside location of the base 160 and the emitter 162. The backside placement allows for separation between the collector 164 and other device elements, improving thermal dissipation and enabling more efficient current collection, and further simplifies the structure of the semiconductor device, reducing the need for complex interconnects that would otherwise be required if all components were located on the frontside.

The entire semiconductor device structure is housed within an N-well tub, which provides an isolated environment for the BJT. This N-well tub serves as a neutral foundation for the device, helping to stabilize the electrical characteristics and prevent unwanted current leakage into surrounding substrate areas. By containing the active regions within the N-well tub, the semiconductor device achieves improved reliability and reduced parasitic capacitance, factors that are particularly beneficial for high-frequency applications.

To enhance isolation further, the semiconductor device is vertically encapsulated with a low-k interlayer dielectric, ILD 170. The ILD 170 surrounds the semiconductor device vertically, insulating each region and reducing parasitic capacitance between adjacent layers. Low-k materials are chosen for their lower dielectric constants, which reduce (e.g., minimize) capacitance and signal delay, allowing the semiconductor device to operate at higher speeds and with reduced power loss. The low-k ILD also provides structural support, preventing unwanted interactions between layers and ensuring the long-term stability of the vertical BJT.

In this embodiment, the vertical configuration allows for effective use of space and enhanced performance, as the current flows vertically from the emitter 162, through the base 160, and down to the collector 164. By positioning the base contact 178 and the emitter contact 180 on the frontside and the collector 164 on the backside, the semiconductor device achieves an efficient design with fewer interconnects and reduced (e.g., minimal) signal loss. Such a structure supports high-speed switching, making the vertical BJT a choice for applications requiring fast and efficient electron flow, such as in RF amplifiers, signal processing, and other high-frequency circuits.

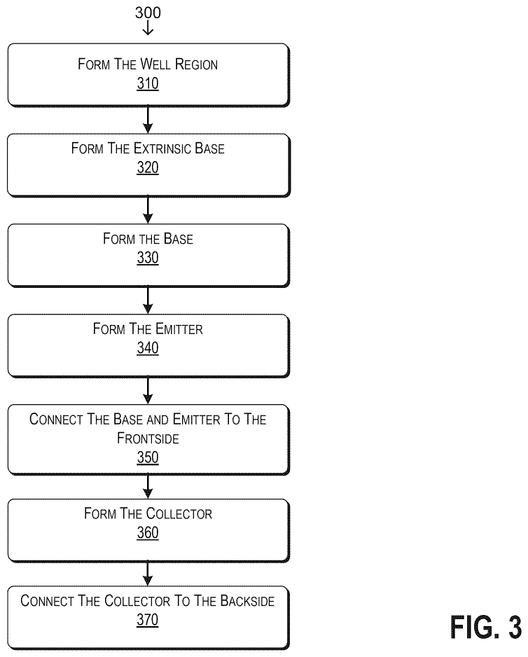

FIG. 3 illustrates a block diagram of a method 300 for forming the semiconductor device, in accordance with some embodiments. As shown by block 310, a well region is formed.

As shown by block 320, an extrinsic base is formed.

As shown by block 330, the base is formed

As shown by block 340, the emitter is formed.

As shown by block 350, the emitter and the base are connected to the frontside of the semiconductor device.

As shown by block 360, the collector is formed

As shown by block 370, an electrical connection between the collector and the backside of the semiconductor device is established.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a base comprising a base contact;
an emitter comprising an emitter contact;
a well region below the base and the emitter;
an extrinsic base between the base and the well region; and
a collector located below the well region and on a backside of the semiconductor device,
wherein the base contact and the emitter contact are connected to a frontside of the semiconductor device.

2. The semiconductor device of claim 1, wherein the semiconductor device further comprises:
a bottom dielectric layer (BILD) below the well region; and
a backside interconnect to wire the collector.

3. The semiconductor device of claim 1, wherein each of the base and the emitter further comprises:
a set of P-type doped regions and a set of N-type doped regions; and
a gate region.

4. The semiconductor device of claim 1, wherein the base contact and the emitter contact are connected to the frontside of the semiconductor device via a frontside interconnect.

5. The semiconductor device of claim 1, wherein the semiconductor device is electrically connected to a back end of line (BEOL) through a via and the base contact and the emitter contact.

6. The semiconductor device of claim 1, further comprising:
shallow trench isolation (STI) on opposite ends of the semiconductor device; and
interlayer dielectric (ILD) located over the base and the emitter.

7. The semiconductor device of claim 1, further comprising:
a backside metal over a backside interconnect; and
a backside contact over the backside metal;
wherein the collector is located over the backside contact, and the collector is encapsulated by the well region.

8. The semiconductor device of claim 1, wherein each of the base and the emitter further comprises alternative layers extended horizontally between two adjacent gate regions.

9. The semiconductor device of claim 8, wherein the alternative layers include silicon.

10. A method of fabricating a semiconductor device, the method comprising:
forming a base comprising a base contact, wherein the base is doped with a first dopant to a first level of doping;
forming an emitter comprising an emitter contact;
forming a well region below the base and the emitter;
forming a collector located below the well region and on a backside of the semiconductor device;
forming an extrinsic base between the base and the well region; and
establishing an electrical connection between the base contact and the emitter contact and a frontside of the semiconductor device.

11. The method of claim 10, further comprising:
forming a bottom dielectric layer (BILD) below the well region; and
forming a backside interconnect to wire the collector.

12. The method of claim 10, wherein forming each of the base and the emitter further comprises:
forming a set of P-type doped regions and a set of N-type doped regions; and
forming a gate region.

13. The method of claim 10, further comprising establishing the electrical connection between the base contact and the emitter contact and a frontside of the semiconductor device via a frontside interconnect.

14. The method of claim 10, further comprising establishing an electrical connection between the semiconductor device and a back end of line (BEOL) through a via and the base contact and the emitter contact.

15. The method of claim 10, further comprising:
forming shallow trench isolation (STI) on opposite ends of the semiconductor device; and
forming interlayer dielectric (ILD) located over the base and the emitter.

16. The method of claim 10, further comprising:
forming a backside metal over a backside interconnect;
forming a backside contact over the backside metal;
forming the collector over the backside contact; and
encapsulating the collector by the well region.

17. The method of claim 10, wherein forming each of the base and the emitter further comprises forming alternative layers extended horizontally between two adjacent gate regions.

18. The method of claim 17, wherein the alternative layers include silicon.

19. The method of claim 10, further comprising forming the base with SiGe.

20. A semiconductor device, comprising:
a base comprising a base contact, the base located on a frontside of the semiconductor device;
an emitter comprising an emitter contact, the emitter located on the frontside of the semiconductor device;
a well region below the base and the emitter; and
a collector located on a backside of the semiconductor device.
